(19) United States
(12) Patent Application Publication
(10) Pub. No.: US 2014/0062470 A1
(43) Pub. Date: Mar. 6, 2014

(54) THREE-DIMENSIONAL IN-PLANE MAGNETIC SENSOR

(71) Applicants: Meng-Huang Lai, Taipei City (TW); Fu-Te Yuan, New Taipei City (TW); Hai-Tao Pan, New Taipei City (TW); Jen-Hwa Hsu, New Taipei City (TW); Ching-Ray Chang, New Taipei City (TW)

(72) Inventors: Meng-Huang Lai, Taipei City (TW); Fu-Te Yuan, New Taipei City (TW); Hai-Tao Pan, New Taipei City (TW); Jen-Hwa Hsu, New Taipei City (TW); Ching-Ray Chang, New Taipei City (TW)

(21) Appl. No.: 13/597,505

(22) Filed: Aug. 29, 2012

(51) Int. Cl. G01R 33/02

(52) U.S. Cl. 324/252

(57) ABSTRACT

A three-dimensional (3D) in-plane magnetic sensor includes a first magnetic sensor, a second magnetic sensor, a third magnetic sensor and a circuit. The first magnetic sensor, second magnetic sensor and third magnetic sensor are installed on a same plane to measure the magnetic field component of first direction, second direction and third direction, where the third direction is perpendicular to the first and second direction. The third magnetic sensor includes a third fixed layer, a third magnetic insulating layer and a third free layer. The magnetoresistance of the third free layer is an intermediate value in the spontaneous magnetization direction, and is varied when interfered by an external magnetic field. In short, the 3D in-plane magnetic sensor is manufactured with semiconductor processing which does not require vertical adhesion, and also bring the benefits of improved production capacity, prolonged product life, reduced manufacturing cost and time.

### BACKGROUND OF THE INVENTION

1. Field of the Invention

The present invention relates to a three-dimensional (3D) in-plane magnetic sensor, which have sensors that can measure x, y and z components of a magnetic field, installed on a same plane through a semiconductor processing.

2. The Prior Arts

In recent years, the demand of electric maps and navigation systems rises remarkably as the technology develops, thus, the need of magnetic sensor also increases accordingly. With the characteristics of magnetic induction, magnetic sensors can be applied to navigation systems and global positioning systems promptly. However, as the size of the navigating products tends to be compact, the design of magnetic sensors is also challenged.

Three magnetic sensors of the exact structures are usually used in the conventional configurations with two of the sensors perpendicular to each other on the same plane for measuring the x and y components of a magnetic field, and the other sensor for measuring the z component. The sensor, which measures the z component, is set up in such way that it is perpendicular to the other two sensors. Nevertheless, as the size of the integrated circuit grows smaller, some difficulties have also risen for the design of magnetic sensors. Due to the vertical adhesion, the manufacturing process has to be broken into two parts and thus it is also hard to be standardized. Hence, the yield rate of the sensors cannot be improved, failures are more likely to happen during the process and the overall production cost rises.

Therefore, a smaller sized magnetic sensor structure, which can be configured such that all three sensors are on the same plane, is needed to overcome the abovementioned problems during the manufacturing process. The first magnetic sensor is configured to measure a first direction component of an external magnetic field.

### SUMMARY OF THE INVENTION

The primary purpose of the present invention is to provide a 3D in-plane magnetic sensor including a first magnetic sensor, a second magnetic sensor, a third magnetic sensor and a circuit with the configuration described as following. The first magnetic sensor is configured to measure a first direction component of an external magnetic field. The second magnetic sensor is configured to measure a second direction component of the external magnetic field, where the second direction is perpendicular to the first direction on a plane. The third magnetic sensor is configured to measure a third direction component of the external magnetic field, where the third direction is perpendicular to both first direction and second direction. The circuit is electrically connected to the first magnetic sensor, the second magnetic sensor and the third magnetic sensor to provide current or voltage thereto. The first magnetic sensor, the second magnetic sensor and the third magnetic sensor are disposed on the same plane.

The third magnetic sensor includes at least one third fixed layer, at least one third magnetic insulating layer and a third free layer, where the third free layer is arranged to be the uppermost layer, the third magnetic insulating layer is arranged between the third fixed layer and also between the third free layer and the uppermost layer of the third fixed layer. The magnetization direction of the at least one third fixed layer is in the third direction or is 180 degrees opposite from the third direction, while the spontaneous magnetization direction of the third free layer is in the first direction, the second direction or tilted from the third direction in the range of 0 to 180 degrees. The magnetoresistance of the third free layer is an intermediate value in the spontaneous direction of the third free layer, however, the magnetoresistance varies when the sensor is interfered by the external magnetic field, thus, the third direction component of the external magnetic field can be measured. The magnetization directions of each third fixed layer are all in the third direction or 180 degrees opposite from the third direction. The third fixed layer can also be a stacked structure, which stacks in an opposite direction from and alternatively with the third magnetic insulating layer. In other words, the magnetization direction of the third fixed layer on the third magnetic insulating layer is in the third direction, and the magnetization direction of the third fixed layer beneath the third magnetic insulating layer is 180 degrees opposite from the third direction.

The present invention is characterized in such that a composite spin valve is formed with the characteristic of tunneling magnetoresistance, so the magnetic sensors for measuring X, Y and Z components of a magnetic field can be set up on the same plane. More importantly, the present invention can be manufactured from the semiconductor processing without the conventional vertical adhesion, therefore the production capacity and yield rate can be increased, the product life span can be prolonged and the production cost and manufacturing time is accordingly reduced.

### BRIEF DESCRIPTION OF THE DRAWINGS

FIG. 1 and FIG. 2 are schematic views showing the components of the 3D in-plane magnetic sensor of the present invention.

### DETAILED DESCRIPTION OF THE PREFERRED EMBODIMENT

The present invention will be apparent to those skilled in the art by reading the following detailed description of preferred embodiments thereof, with reference to the attached drawings.

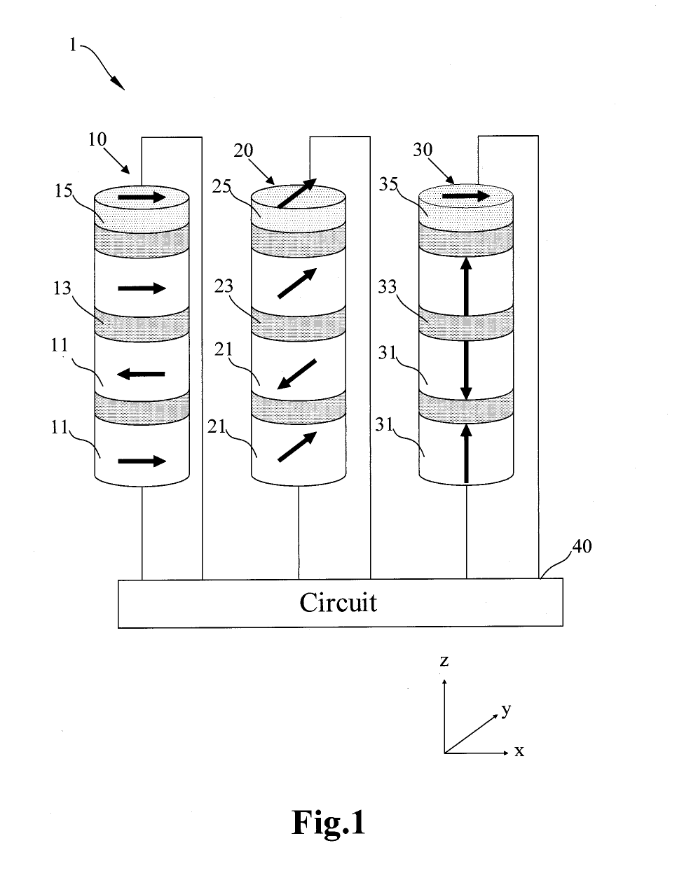

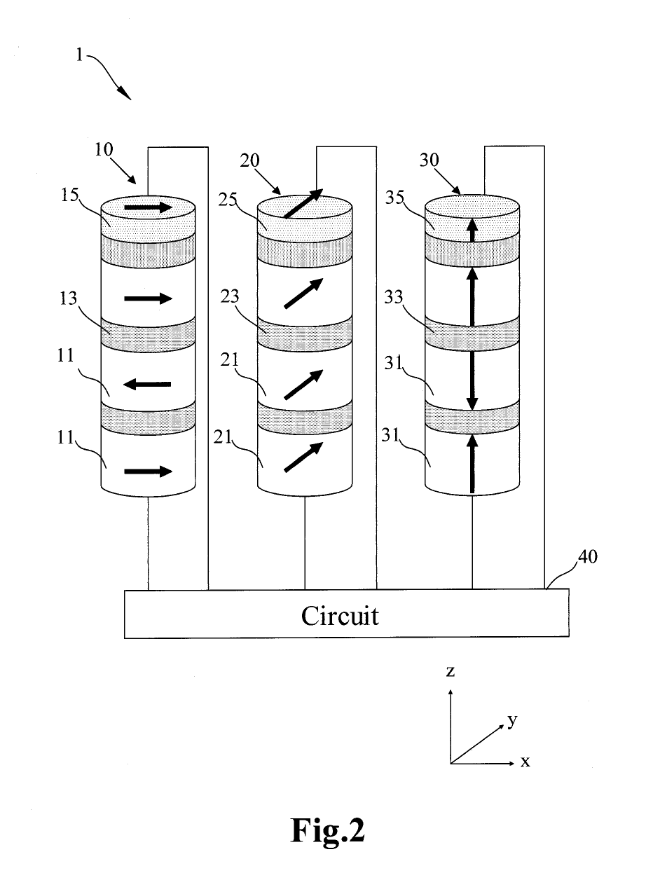

FIG. 1 and FIG. 2 are the schematic views showing the components of the 3D in-plane magnetic sensor of the present invention. As shown in FIG. 1 and FIG. 2, the 3D planer magnetic sensor 1 of the present invention includes a first magnetic sensor 10, a second magnetic sensor 20, a third magnetic sensor 30 and a circuit 40. The first magnetic sensor 10, the second magnetic sensor 20 and the third magnetic sensor 30 are set up on the same plane with the circuit 40 electrically connected to all of them.

The first magnetic sensor 10 includes at least one first fixed layer 11, at least one first magnetic insulating layer 13 and at least one first free layer 15. The first free layer 15 is arranged to be the uppermost layer, while the first magnetic insulating layer 13 is arranged between the first fixed layer 11 and also between the first free layer 15 and the uppermost layer of the first fixed layer 11. The spontaneous magnetization direction of the first free layer 15 is in the first direction and the magnetoresistance of the first free layer 15 is at its minimum value in the first direction. When the sensor is interfered by the external magnetic field, the magnetization direction of the first free layer 15 offsets and the magnetoresistance thereof increases, thus the first direction component of the external magnetic field can be calculated through the change in the magnetoresistance. The magnetization directions of each first fixed layer 11 are all in the first direction or 180 degrees opposite from the first direction. The first fixed layer 11 can also be a stacked structure, which stacks in an opposite direction from and alternatively with the first magnetic insulating layer 13. In other words, the magnetization direction of the first fixed layer 11 on the first magnetic insulating layer 13 is in the first direction, and the magnetization direction of the first fixed layer 11 beneath the first magnetic insulating layer 13 is 180 degrees opposite from the first direction.

The second magnetic sensor 20 includes at least one second fixed layer 21, at least one second magnetic insulating layer 23 and at least one second free layer 25. The second layer 25 is arranged to be the uppermost layer, while the second magnetic insulating layer 23 is arranged between the second fixed layer 21 and also between the second free layer 25 and the uppermost layer of the second fixed layer 21. The spontaneous magnetization direction of the second free layer 25 is in the second direction and the magnetoresistance of the second free layer 25 is at its minimum value in the second direction, where the second direction is perpendicular to the first direction on the same plane. When the sensor is interfered by the external magnetic field, the magnetization direction of the second free layer 25 offsets and the magnetoresistance thereof increases, thus the second direction component of the external magnetic field can be calculated through the change in the magnetoresistance. The magnetization directions of each second fixed layer 21 are all in the second direction or 180 degrees opposite from the second direction. The second fixed layer 21 can also be a stacked structure, which stacks in an opposite direction from and alternatively with the second magnetic insulating layer 23. In other words, the magnetization direction of the second fixed layer 21 on the second magnetic insulating layer 23 is in the second direction, and the magnetization direction of the second fixed layer 21 beneath the second magnetic insulating layer 23 is 180 degrees opposite from the second direction.

The third magnetic sensor 30 includes at least one third fixed layer 31, at least one third magnetic insulating layer 33 and at least one third free layer 35. The third layer 35 is arranged to be the uppermost layer, while the third magnetic insulating layer 33 is arranged between the third fixed layer 31 and also between the third free layer 35 and the uppermost layer of the third fixed layer 31. The magnetization directions of the third fixed layer 31 can all be in the third direction or 180 degrees opposite from the third direction, where the third direction is perpendicular to both the first and second directions. The spontaneous magnetization direction of the third free layer 35 is in the first direction, second direction or in a direction, which is tilted from the third direction in the range of 0˜180 degrees. The magnetoresistance of the third free layer 35 is an intermediate value in the spontaneous magnetization direction. When the sensor is interfered by the external magnetic field, the magnetization direction of the third free layer 35 offsets and the magnetoresistance thereof increases or decreases correspondingly, thus the third direction component of the external magnetic field can be calculated through the change in the magnetoresistance. The magnetization directions of each third fixed layer 31 are all in the third direction or 180 degrees opposite from the third direction. The third fixed layer 31 can also be a stacked structure, which stacks in an opposite direction from and alternatively with the third magnetic insulating layer 33. In other words, the magnetization direction of the third fixed layer 31 on the third magnetic insulating layer 33 is in the third direction, and the magnetization direction of the third fixed layer 31 beneath the third magnetic insulating layer 33 is 180 degrees opposite from the third direction.

The circuit 40 is electrically connected to the first magnetic sensor 10, the second magnetic sensor 20 and the third magnetic sensor 30 to provide current to pass through the first magnetic sensor 10, the second magnetic sensor 20 and the third magnetic sensor 30. The current or voltage will cause the first free layer 15, the second free layer 25 and the third free layer 35 to become magnetic, so the change in magnetoresistance of the first free layer 15, the second free layer 25 and the third free layer 35 can be measured. The measured change in magnetoresistance is then transformed into a current or voltage signal and sent to an external computing device (not shown in graph). The 3D in-plane magnetic sensor with previously described configuration can thus be applied to various magnetic positioning devices.

The material of the first fixed layer 11 and the second fixed layer 21 can be at least one of the following ferromagnetic alloys: iron, cobalt, nickel, cobalt-iron-boron alloy, nickel-iron alloy, cobalt-iron alloy, face-centered cobalt-platinum alloy, L1₀ cobalt-platinum alloy, face-centered iron-platinum alloy and L1₀ iron-platinum alloy. The material of the third fixed layer 31 can be at least one of the following ferromagnetic alloys or ferromagnetic alloy multilayered films: iron, cobalt, nickel, cobalt-iron-boron alloy, mD₀19 cobalt-platinum alloy, L1₀ iron-palladium alloy, L1₀ cobalt-platinum alloy, L1₁-cobalt-platinum alloy, L1₀ iron-platinum alloy, cobalt/platinum multilayer stack structure, cobalt/palladium multilayer stack structure, nickel/palladium multilayer stack structure, nickel/platinum multilayer stack structure, cobalt-iron-boron alloy/platinum multilayer stack structure, cobalt-iron-boron alloy/palladium multilayer stack structure, nickel-iron alloy/platinum multilayer stack structure, nickel-iron alloy/palladium multilayer stack structure, cobalt-iron alloy/platinum multilayer stack structure and cobalt-iron/palladium multilayer stack structure.

The material of the first free layer 15 and the second free layer 25 can be at least one of the following ferromagnetic alloys: iron, cobalt, nickel, cobalt-iron-boron alloy, nickel-iron alloy, cobalt-iron alloy and cobalt-nickel alloy. The material of the third free layer 35 can be at least one of the following ferromagnetic alloys or ferromagnetic alloy multilayered films: iron, cobalt, nickel, cobalt-iron-boron alloy, mD₀19 cobalt-platinum alloy, L1₀ cobalt-platinum alloy, L1₁-cobalt-platinum alloy, L1₀ iron-platinum alloy, L1₀ iron-palladium alloy, cobalt/platinum multilayer stack structure, cobalt/palladium multilayer stack structure, nickel/palladium multilayer stack structure, nickel/platinum multilayer stack structure, cobalt-iron-boron alloy/platinum multilayer stack structure, cobalt-iron-boron alloy/palladium multilayer stack structure, nickel-iron alloy/platinum multilayer stack structure, nickel-iron alloy/palladium multilayer stack structure, cobalt-iron alloy/platinum multilayer stack structure and cobalt-iron/palladium multilayer stack structure.

The first magnetic insulating layer 13 and the second magnetic insulating layer 23 can be made from a non-magnetic metal or an electromagnetic insulator, and the third magnetic insulating layer 33 is made from an electromagnetic insulator as well. The non-magnetic metal includes at least one of the following: ruthenium, tantalum, chromium, titanium, copper, palladium, molybdenum and niobium, while the electromagnetic insulator at least includes one of the following: magnesium oxide, aluminum oxide, tantalum oxide and silicon oxide.

The present invention is characterized in such that a composite spin valve is formed with the characteristic of tunneling magnetoresistance, so the magnetic sensors for measuring X, Y and Z components of a magnetic field can be set up on the same plane. More importantly, the present invention can be manufactured from the semiconductor processing without the conventional vertical adhesion, therefore the production capacity and yield rate can be increased, the product life span can be prolonged and the production cost and manufacturing time is accordingly reduced.

The preferred embodiment described above is disclosed for illustrative purpose but to limit the modifications and variations of the present invention. Thus, any modifications and variations made without departing from the spirit and scope of the invention should still be covered by the scope of this invention as disclosed in the accompanying claims.

What is claimed is:

1. A three-dimensional (3D) in-plane magnetic sensor comprising:
a first magnetic sensor configured to measure a first direction component of an external magnetic field;
a second magnetic sensor configured to measure a second direction component of said external magnetic field, where said second direction is perpendicular to said first direction on a plane;
a third magnetic sensor including at least one third fixed layer, at least one third magnetic insulating layer and a third free layer, where said third free layer is arranged to be the uppermost layer, said third magnetic insulating layer is arranged between said third fixed layer and also between said third free layer and the uppermost layer of said third fixed layer, wherein, a magnetization direction of said third fixed layer is in a third direction or is 180 degrees opposite from said third direction, said third direction is perpendicular to both said first direction and said second direction, while the spontaneous magnetization direction of said third free layer is in said first direction, said second direction or tilted from said third direction in the range of 0 to 180 degrees; a magnetoresistance is an intermediate value in the spontaneous magnetization direction of said third free layer, however, when interfered by said external magnetic field, the magnetoresistance varies, thus said third direction component of said external magnetic field can be measured; and
a circuit electrically connected to said first magnetic sensor, said second magnetic sensor and said third magnetic sensor to provide a current or voltage to said first magnetic sensor, said second magnetic sensor and said third magnetic sensor, wherein said first magnetic sensor, said second magnetic sensor and said third magnetic sensor are disposed on the same plane.

2. The 3D in-plane magnetic sensor as claimed in claim 1, wherein the magnetization directions of said third fixed layer are all in said third direction, or are all 180 degrees opposite from said third direction.

3. The 3D in-plane magnetic sensor as claimed in claim 1, wherein the magnetization direction of said third fixed layer on said third magnetic insulating layer is in said third direction, and the magnetization direction of said third fixed layer beneath said third magnetic insulating layer is 180 degrees opposite from said third direction.

4. The 3D in-plane magnetic sensor as claimed in claim 1, wherein said first magnetic sensor includes at least one first fixed layer, at least one first magnetic insulating layer and at least one first free layer, said first free layer is arranged to be the uppermost layer, said first magnetic insulating layer is arranged between said first fixed layer and also between said first free layer and the uppermost layer of said first fixed layer, wherein, the magnetization direction of said first fixed layer is in said first direction or is 180 degrees opposite from said first direction, while the spontaneous magnetization direction of said first free layer is in said first direction and the magnetoresistance of said first free layer is at its minimum value in said first direction, when interfered by said external magnetic field, thereby increasing the magnetoresistance, and thus measuring said first direction component of said external magnetic field; said second magnetic sensor including at least one second fixed layer, at least one second magnetic insulating layer and at least one second free layer, said second free layer being arranged to be the uppermost layer, said second magnetic insulating layer being arranged between said at least one second fixed layer and also between said second free layer and the uppermost layer of said at least one second fixed layer, wherein, the magnetization direction of said at least one second fixed layer is in said second direction or is 180 degrees opposite from said second direction, while the spontaneous magnetization direction of said second free layer is in said second direction and the magnetoresistance of said second free layer is at its minimum value in said second direction, when interfered by said external magnetic field, thereby increasing the magnetoresistance, and thus measuring said second direction component of said external magnetic field.

5. The 3D in-plane magnetic sensor as claimed in claim 4, wherein the magnetization directions of said first fixed layer are all in said first direction, or are all 180 degrees opposite from said first direction.

6. The 3D in-plane magnetic sensor as claimed in claim 4, wherein the magnetization directions of said second fixed layer are all in said second direction, or are all 180 degrees opposite from said second direction.

7. The 3D in-plane magnetic sensor as claimed in claim 4, wherein the magnetization direction of said first fixed layer on said first magnetic insulating layer is in said first direction, and the magnetization direction of said first fixed layer beneath said first magnetic insulating layer is 180 degrees opposite from said first direction.

8. The 3D in-plane magnetic sensor as claimed in claim 4, wherein the magnetization direction of said second fixed layer on said second magnetic insulating layer is in said second direction, and the magnetization direction of said second fixed layer beneath said second magnetic insulating layer is 180 degrees opposite from said second direction.

9. The 3D in-plane magnetic sensor as claimed in claim 4, wherein when said circuit provides said current or voltage, said current passes through said first magnetic sensor, said second magnetic sensor and said third magnetic sensor, thereby permitting measuring of the change in magnetoresistance in said first magnetic sensor, said second magnetic sensor and said third magnetic sensor.

10. The 3D in-plane magnetic sensor as claimed in claim 1, wherein said third magnetic insulating layer is made from an electromagnetic insulator, said electromagnetic insulator includes at least one of the following: magnesium oxide (MgO), aluminum oxide (Al₂O₃), tantalum oxide (Ta₂O₅) and silicon oxide (SiO₂).

11. The 3D in-plane magnetic sensor as claimed in claim 1, wherein the material of said third fixed layer is at least one of the following ferromagnetic alloys or ferromagnetic alloy multilayered films: iron, cobalt, nickel, cobalt-iron-boron alloy, mD₀19 cobalt-platinum alloy, L1₀ iron-palladium alloy, L1₀ cobalt-platinum alloy, L1₁-cobalt-platinum alloy, L1₀ iron-platinum alloy, cobalt/platinum multilayer stack structure, cobalt/palladium multilayer stack structure, nickel/palladium multilayer stack structure, nickel/platinum multilayer stack structure, cobalt-iron-boron alloy/platinum multilayer stack structure, cobalt-iron-boron alloy/palladium multilayer stack structure, nickel-iron alloy/platinum multilayer stack structure, nickel-iron alloy/palladium multilayer stack structure, cobalt-iron alloy/platinum multilayer stack structure and cobalt-iron/palladium multilayer stack structure; the material of said third free layer is at least one of the following ferromagnetic alloys or ferromagnetic alloy multilayered films: iron, cobalt, nickel, cobalt-iron-boron alloy, mD₀19 cobalt-platinum alloy, L1₀ cobalt-platinum alloy, L1₁-cobalt-platinum alloy, L1₀ iron-platinum alloy, L1₀ iron-palladium alloy, cobalt/platinum multilayer stack structure, cobalt/palladium multilayer stack structure, nickel/palladium multilayer stack structure, nickel/platinum multilayer stack structure, cobalt-iron-boron alloy/platinum multilayer stack structure, cobalt-iron-boron alloy/palladium multilayer stack structure, nickel-iron alloy/platinum multilayer stack structure, nickel-iron alloy/palladium multilayer stack structure, cobalt-iron alloy/platinum multilayer stack structure and cobalt-iron/palladium multilayer stack structure.

12. The 3D in-plane magnetic sensor as claimed in claim 4, wherein the material of said first fixed layer and second fixed layer is at least one of the following ferromagnetic alloys: iron, cobalt, nickel, cobalt-iron-boron alloy, nickel-iron alloy, cobalt-iron alloy, face-centered cobalt-platinum alloy, L1₀ cobalt-platinum alloy, L1₁ cobalt-platinum alloy, face-centered iron-platinum alloy and L1₀ iron-platinum alloy; the material of said first free layer and second free layer is at least one of the following ferromagnetic alloys: iron, cobalt, nickel, cobalt-iron-boron alloy, nickel-iron alloy, cobalt-iron alloy and cobalt-nickel alloy.

13. The 3D in-plane magnetic sensor as claimed in claim 4, wherein said first magnetic insulating layer and said second magnetic insulating layer are made from a non-magnetic metal or an electromagnetic insulator, where said non-magnetic metal at least includes one of ruthenium, tantalum, chromium, titanium, copper, palladium, molybdenum and niobium, while said electromagnetic insulator at least includes one of magnesium oxide, aluminum oxide, tantalum oxide and silicon oxide.
